(19) United States
(12) Patent Application Publication
(10) Pub. No.: US 2026/0353624 A1
(43) Pub. Date: Nov. 5, 2026

(54) MOUNTING ASSISTANCE DEVICE

(71) Applicant: FUJI CORPORATION, Chiryu (JP)

(72) Inventors: Mikiya SUZUKI, Nishio-shi (JP); Yuta YOKOI, Kariya-sh (JP); Yuji KAWASAKI, Nagoya-shi (JP)

(73) Assignee: FUJI CORPORATION, Chiryu (JP)

(21) Appl. No.: 19/486,058

(22) PCT Filed: Jul. 5, 2023
(86) PCT No.: PCT/JP2023/025024

§ 371 Date: Nov. 20, 2025

(51) Int. Cl. H05K 13/08; H05K 13/04

(52) U.S. Cl. CPC H05K 13/0813; H05K 13/043

(57) ABSTRACT

A mounting assistance device to be applied to a component mounter configured to collect a component from a component supply device equipped with a bulk feeder having multiple cavities each of which accommodates a component in a supply region where the component is supplied to be collectable, the component mounter being configured to mount the component on a board, includes an acquisition section configured to perform image processing on initial image data acquired by capturing the supply region in a state where the components are removed from the supply region, and acquire cavity information on the multiple cavities.

### TECHNICAL FIELD

The present disclosure relates to a mounting assistance device.

### BACKGROUND ART

A mounting assistance device assists a mounting process by a component mounter using a bulk feeder. The bulk feeder is mounted on a component mounter that mounts a component on a board, and supplies components in a bulk state (refer to Patent Literature 1). In a mounting process, a component mounter performs image processing for recognizing a supply state of components by a bulk feeder, and controls an operation of picking up components by using a suction nozzle based on a result of the image processing.

### CITATION LIST

### Patent Literature

Patent Literature 1: WO 2021/095219

### BRIEF SUMMARY

### Technical Problem

Image processing for recognizing a supply state includes determination of whether components are accommodated in multiple cavities formed in a supply region of a bulk feeder so as to be collectable. When there is an erroneous determination in such image processing, the erroneous determination may cause a mistake in a collection operation, and even when collection can be performed, processing to be performed thereafter may be influenced.

An object of the present description is to provide a bulk feeder suitable for image processing for recognizing a supply state, and to provide a mounting assistance device that assists a mounting process by improving accuracy of the image processing.

### Solution to Problem

The present description discloses a mounting assistance device to be applied to a component mounter configured to collect a component from a component supply device equipped with a bulk feeder having multiple cavities each of which accommodates a component in a supply region where the component is supplied to be collectable, the component mounter being configured to mount the component on a board, the mounting assistance device including an acquisition section configured to perform image processing on initial image data acquired by capturing the supply region in a state where the components are removed from the supply region, and acquire cavity information on the multiple cavities.

### Advantageous Effects

With such a configuration, accuracy of image processing can be improved. Accordingly, it is possible to prevent a mistake from occurring in a collection operation by a component mounter, and as a result, it is possible to maintain high productivity of the component mounter.

### BRIEF DESCRIPTION OF DRAWINGS

FIG. 1 is a plan view schematically illustrating a component mounter.

FIG. 2 is a side view schematically illustrating a part of a bulk feeder including a supply region.

FIG. 3 is a plan view when viewed from a direction III of FIG. 2.

FIG. 4 is a block diagram illustrating a component mounter to which a mounting assistance device is applied.

FIG. 5 is a flowchart illustrating recognition processing of a supply state.

FIG. 6 is a view illustrating image data acquired by capturing a supply region.

FIG. 7 is an enlarged view illustrating image data subjected to blob generation processing.

FIG. 8 is a diagram illustrating a design-based cavity superimposed on initial image data.

FIG. 9 is a flowchart illustrating update processing of cavity information.

FIG. 10 is a flowchart illustrating acquisition processing of initial image data.

FIG. 11A is a diagram of a first example illustrating before and after blob removal processing and a recognition component.

FIG. 11B is a diagram of a second example illustrating before and after blob removal processing and a recognition component.

### DESCRIPTION OF EMBODIMENTS

### 1. Overview of Mounting Assistance Device 50

Mounting assistance device 50 assists a mounting process by component mounter 10 using bulk feeder 30. In the present embodiment, mounting assistance device 50 is incorporated in control device 20 of component mounter 10. Mounting assistance device 50 improves accuracy of image processing for recognizing a supply state of a component supplied by bulk feeder 30, thereby suppressing occurrence of a mistake in a collection operation in a mounting process.

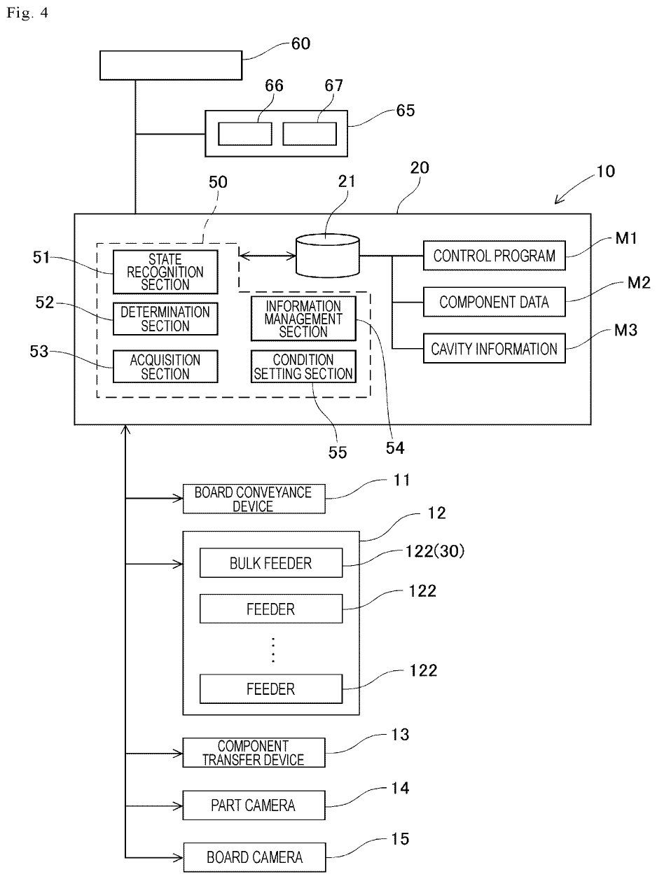

Component mounter 10 performs a mounting process of mounting components on board 91 as a predetermined board work. Component mounter 10 is installed in a conveyance direction of board 91 together with other board work machines to configure a production line. Each of multiple board work machines is communicably connected to host computer 60 (see FIG. 4) that collectively controls the production line. The production line includes a printer, component mounter 10, a reflow oven, and an inspection machine as the multiple board work machines.

Setup device 65 is an external device used for setup of feeder 122 used for a mounting process to be performed. Setup device 65 is used for, for example, an operation of loading a component on feeder 122, an operation of detaching the component from feeder 122 that has been used for a mounting process, and the like. Setup device 65 includes support table 66 that supports feeder 122 or a part of a unit detached from feeder 122. Setup device 65 includes dedicated camera 67 that can capture an image of supply region As of bulk feeder 30 supported by support table 66. Setup device 65 is communicably connected to host computer 60, and receives and outputs various information related to setup.

### 2. Configuration of Component Mounter 10

### 2-1. Board Conveyance Device 11

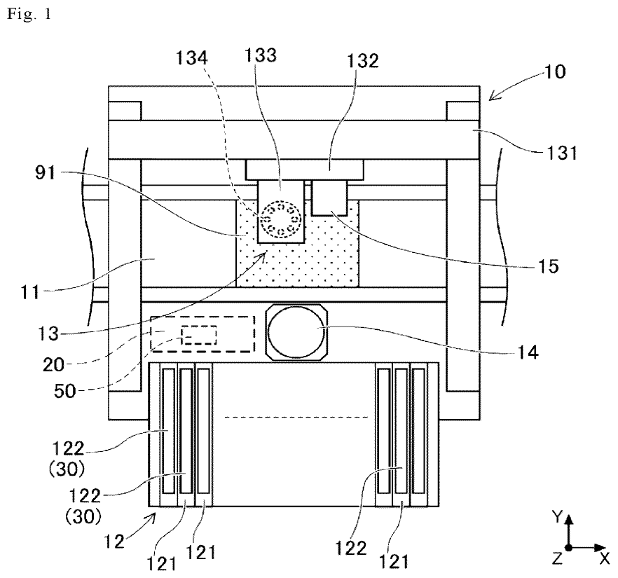

As illustrated in FIG. 1, component mounter 10 includes board conveyance device 11. Board conveyance device 11 consecutively conveys boards 91 in a conveyance direction and positions board 91 at a predetermined position inside a component mounter.

### 2-2. Component Supply Device 12

Component mounter 10 includes component supply device 12. Component supply device 12 supplies a component to be mounted on board 91. In component supply device 12, feeder 122 is set to each of multiple slots 121. A tape feeder that supplies components to be collectable by feeding and moving a carrier tape accommodating multiple components is applied to feeder 122. In addition, bulk feeder 30 that supplies components accommodated in a bulk state to be collectable is applied to feeder 122. Details of bulk feeder 30 will be described below.

### 2-3. Component Transfer Device 13

Component mounter 10 includes component transfer device 13. Component transfer device 13 transfers a component supplied by component supply device 12 to a predetermined mounting position on board 91. Component transfer device 13 includes head drive device 131, mounting body 132, mounting head 133, and suction nozzle 134. Head drive device 131 moves mounting body 132 in a horizontal direction (X direction and Y direction) by a linear movement mechanism. Mounting head 133 is detachably fixed to mounting body 132 by a clamp member (not illustrated) and is provided to be movable in a horizontal direction inside a component mounter.

Mounting head 133 supports multiple suction nozzles 134 to be rotatable and liftable/lowerable. Suction nozzle 134 is a holding member that collects and holds a component supplied by feeder 122. Suction nozzle 134 picks up a component supplied by feeder 122 by using negative pressure air that is supplied. A chuck or the like that holds a component by gripping the component can be adopted as a holding member attached to mounting head 133.

### 2-4. Part Camera 14 and Board Camera 15

Component mounter 10 includes part camera 14 and board camera 15. Part camera 14 and board camera 15 are digital imaging devices including imaging elements such as CMOS. Part camera 14 and board camera 15 capture images based on a control signal and send image data acquired by the image-capturing. Part camera 14 is configured to capture an image of the component held by suction nozzle 134 from below. Board camera 15 is provided on mounting body 132 movably in the horizontal direction and integrally with mounting head 133. Board camera 15 is configured to capture an image of board 91 from above.

In addition, board camera 15 can set a surface of board 91 as an imaging target and can also set various apparatuses and the like as imaging targets within a movable range of mounting body 132. For example, in the present embodiment, as illustrated in FIG. 3, board camera 15 can capture an image of supply region As to which bulk feeder 30 supplies a component and reference mark 49 provided on an upper portion of bulk feeder 30 within a field of view of a camera. As described above, board camera 15 can be used commonly to capture images of different imaging targets to acquire image data used for various types of image processing.

### 2-5. Control Device 20

As illustrated in FIG. 1, component mounter 10 includes control device 20. Control device 20 is mainly configured with CPU, various types of memories, and a control circuit. Control device 20 includes storage section 21 as illustrated in FIG. 4. Storage section 21 is configured with a hard disk device or a storage device such as flash memory. Storage section 21 of control device 20 stores various data such as control program M1, component data M2, and cavity information M3, which are used for controlling a mounting process.

Control program M1 indicates, in a scheduled mounting order, a mounting position, a mounting angle, and a component type of a component to be mounted on board 91 in the mounting process. Here, the mounting process includes a process of repeating multiple times a pick-and-place cycle (PP cycle) including a collection cycle and a mounting cycle. The above-described “collection cycle” is a process of repeating multiple times a collection operation of collecting, by using suction nozzle 134, the components supplied by component supply device 12.

In addition, the above-described “mounting cycle” is a process of repeating multiple times a mounting operation of mounting a collected component at a predetermined mounting position of board 91 and at a predetermined mounting angle. As described above, a performance order of the PP cycle configured with multiple collection operations and mounting operations grouped in consideration of the number of suction nozzles 134 supported by mounting head 133, a movement distance of mounting head 133, and the like is set in advance in control program M1.

Component data M2 includes shape data for each type of component. The above-described “shape data” includes at least one of an outer edge shape of a component, a shape of a characteristic portion of the component, and a dimension of the component. The “outer edge shape” of a component corresponds to a shape of an outer edge when the inside and a background of the component are divided with the outer edge of the component as a boundary.

The “shape of a characteristic portion” of a component corresponds to a boundary shape of the characteristic portion in appearance due to a shape, a pattern, a color, and the like of the component. A corner portion, a bump, a terminal, a lead portion, and the like of a component can be applied as the characteristic portion of the component. In addition to the shape data, component data M2 can include, for example, a maximum allowable movement speed (acceleration), a collection position (for example, a position in contact with suction nozzle 134), and the like for each component.

Cavity information M3 is information related to cavities 45 that are formed in supply region As of bulk feeder 30 and individually accommodate components. In the present embodiment, cavity information M3 includes a shape (including a length and a depth of each side), a position, an orientation, the type of corresponding component, and the like of cavity 45 in supply region As. Cavity information M3 is stored in association with identification information (ID) of bulk feeder 30. Details of a process of acquiring cavity information M3 and applying cavity information M3 will be described below.

Control device 20 performs recognition processing of a holding state of a component held by each of multiple holding members (suction nozzles 134). Specifically, control device 20 performs image processing on the image data acquired by capturing with part camera 14 and recognizes a position and an angle of each component with respect to a reference position of mounting head 133. In addition to part camera 14, for example, control device 20 may perform image processing on the image data acquired by capturing a component from a side, below, or above by using a head camera unit or the like integrally provided on mounting head 133.

In a mounting process, control device 20 controls a mounting operation performed by mounting head 133 such that a component is mounted on board 91 in a predetermined posture. In this case, control device 20 controls the mounting operation based on a holding state of the recognized component. That is, control device 20 corrects a position of mounting head 133 and an angle of suction nozzle 134 around a Q-axis to correct deviations of a position and an angle of a component held by suction nozzle 134 with respect to the Q-axis (rotation axis of suction nozzle 134). As a result, a component held by suction nozzle 134 is mounted at a predetermined mounting position and a predetermined mounting angle which are instructed by control program M1.

### 3. Configuration of Bulk Feeder 30

Bulk feeder 30 is set in component mounter 10 to function as a part of component supply device 12. Bulk feeder 30 supplies the components accommodated in a component case in a bulk state (a state in which each posture is irregular and dispersed) that is not packaged like a carrier tape. Accordingly, unlike a tape feeder, since bulk feeder 30 does not use a carrier tape, there is a merit in that loading of a carrier tape, collection of the used tape, and the like can be omitted.

For example, there is bulk feeder 30 of a type that supplies a component in an irregular posture to supply region As having a plane shape. However, when components are so close to be in contact with each other or piled up (in a state of being overlapped in an up-down direction) or the components stand sideways such that width directions of the components are oriented vertically in supply region As, component mounter 10 cannot regard the components as collection targets. Therefore, in order to increase a ratio of components that are available for collection, there is bulk feeder 30 of a type that supplies components in a state in which components are aligned in supply region As. In the present embodiment, bulk feeder 30 of a type in which components are aligned will be described as an example.

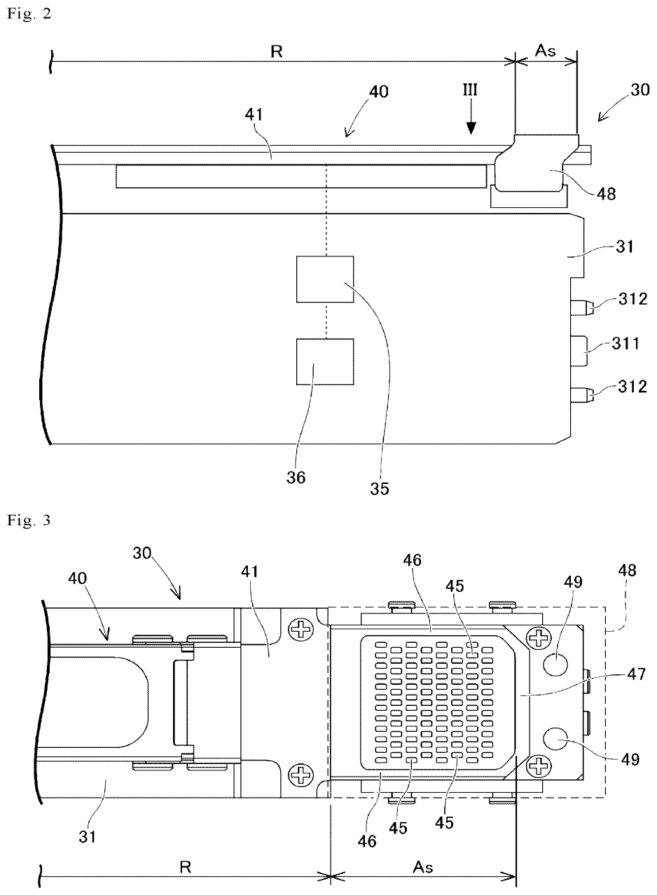

Bulk feeder 30 is provided with track unit 40 that can vibrate and is detachably attached to feeder main body 31 formed in a flat box shape. Connector 311 and two positioning pins 312 are provided on a front portion (right side end portion in FIG. 2) of feeder main body 31. When feeder main body 31 is set in slot 121 of component supply device 12, power is supplied via connector 311, and feeder main body 31 is communicable with control device 20 of component mounter 10.

Track unit 40 is vibrated by vibration application device 35. Track unit 40 has track main body 41. Track main body 41 is formed with conveyance path R through which multiple components are conveyed, and supply region As that communicates with conveyance path R and opens upwards such that the multiple components can be collected. Track main body 41 is formed to extend in a front-rear direction (left-right direction in FIG. 3) of feeder main body 31. Pair of side walls 46, which projects upwards, is formed along both edges in a width direction (up-down direction in FIG. 3) of track main body 41. Pair of side walls 46 are wall members that surround a peripheral edge of conveyance path R together with tip portion 47 of track main body 41 and prevent the components conveyed along conveyance path R from leaking out.

As illustrated in FIG. 3, multiple cavities 45 that can accommodate components are formed in supply region As of track main body 41. Each of multiple cavities 45 is open upward to accommodate components in a posture in which a thickness direction of the component is in an up-down direction. In the present embodiment, multiple cavities 45 are arranged in a staggered shape. Multiple cavities 45 are configured with, for example, one or more plate-shaped members (for example, a plate member for the bottom of a cavity and a plate member for a side surface of the cavity). Track unit 40 is a unitized track member in which a plate member selected according to shapes of multiple types of components are attached to common track main body 41.

Here, “supply region As” of track unit 40 is a region to which a component is supplied in a bulk state, and is a region from which a component can be collected by suction nozzle 134 supported by mounting head 133. In addition, “conveyance path R” of track unit 40 is a component passage through which a component being flowed from a component case side to track unit 40 is conveyed to supply region As.

In addition, vibration application device 35 vibrates track unit 40 such that multiple components are conveyed along conveyance path R. When track unit 40 vibrates, forward and upward external force or a rearward and upward external force is applied to a component. As a result, multiple components are conveyed either to a front side or a rear side of track unit 40. Bulk feeder 30 conveys a component when an operation of vibration application device 35 is controlled by feeder control device 36, and performs a supply operation of the component to supply region As. When components are accommodated in multiple cavities 45 by the supply operation, suction nozzle 134 is in a state of being able to collect the components.

Shutter 48 that can close an opening of supply region As is provided in an upper portion of track unit 40. When track unit 40 is attached to feeder main body 31, opening and closing operations of shutter 48 are controlled by a shutter drive device (not illustrated). By opening and closing shutter 48, bulk feeder 30 can prevent a component from exiting and a foreign matter from entering supply region As.

Reference mark 49 indicates reference position Pf of supply region As. In the present embodiment, reference marks 49 are provided in a pair in a width direction of bulk feeder 30, and are formed in a circular shape. Reference position Pf indicates, for example, an original point of supply region As, and is set at an intermediate point of reference mark 49 in the present embodiment.

### 4. Configuration of Mounting Assistance Device 50

A configuration of mounting assistance device 50 will be described with reference to FIGS. 4 to 11B. Mounting assistance device 50 assists recognition processing of a supply state of a component which is performed by control device 20 of component mounter 10 in a mounting process. The recognition processing of the supply state includes image processing, and the image processing includes a determination of whether a component supplied to supply region As of bulk feeder 30 is suitable for a target of a collection operation by component mounter 10.

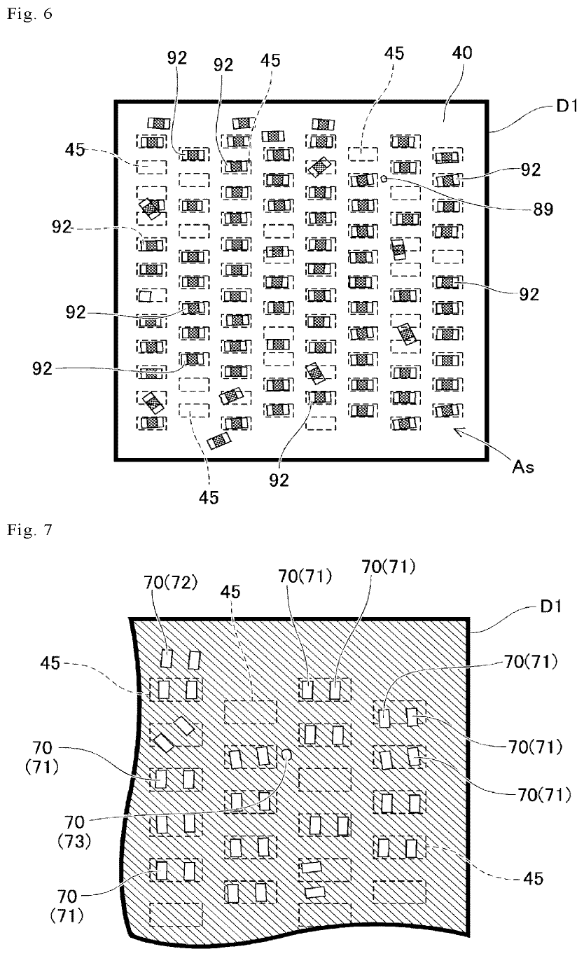

Specifically, control device 20 performs image processing on image data D1 (see FIG. 6) acquired by capturing with a camera (board camera 15 in the present embodiment), recognizes whether there is a suitable component for a target of a collection operation in supply region As, and recognizes a position and an angle of the component when there is a suitable component for the collection operation. Then, control device 20 controls an operation of mounting head 133 in a collection operation based on a result of recognition processing of a supply state.

In the above-described suitableness determination, when there is an erroneous determination in the image processing such as erroneously recognizing some of multiple components as one component or erroneously recognizing a foreign matter as a part of a component, a position and a posture of the recognized component (hereinafter, also referred to as a “recognition component”) are different from an actual position and an actual posture, which can cause a mistake in the collection operation. In addition, even when a component can be collected, there is a possibility that processing to be performed thereafter, for example, a component transfer operation or a component mounting operation is influenced.

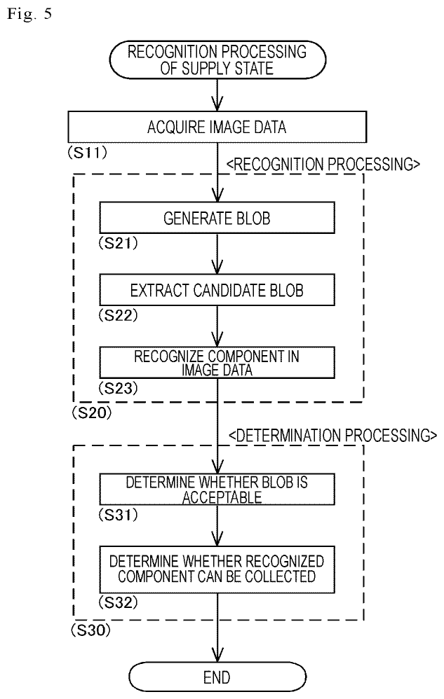

Therefore, in the present embodiment, mounting assistance device 50 incorporated in control device 20 of component mounter 10 adopts a configuration that can improve accuracy of image processing included in recognition processing (see FIG. 5) of a supply state of a component. Specifically, as illustrated in FIG. 4, mounting assistance device 50 includes acquisition section 53. Furthermore, mounting assistance device 50 may include state recognition section 51, determination section 52, information management section 54, and condition setting section 55.

In the recognition processing of a supply state of a component, as illustrated in FIG. 5, mounting assistance device 50 acquires image data D1 acquired by capturing with board camera 15 (S11). State recognition section 51 performs recognition processing (S20) by using image data D1. Determination section 52 performs determination processing (S30) for determining whether a component is a suitable component for a collection operation.

### 4-1. State Recognition Section 51

State recognition section 51 performs image processing on image data D1 acquired by capturing supply region As in which multiple cavities 45 for individually accommodating multiple components 92 are formed, and acquires information on recognition component 80. In the present embodiment, blob analysis is adopted as a method of recognizing components 92 scattered in supply region As as recognition components 80.

Specifically, state recognition section 51 first performs generation step (S21) of generating multiple blobs 70 for image data D1. In detail, state recognition section 51 performs binarization of image data D1 with a predetermined threshold, and, for example, sets white when a luminance value of each pixel is higher than the threshold, and sets black when the luminance value is lower than or equal to the threshold. FIG. 7 illustrates a part of binarized image data D1 in an enlarged manner, and cavities 45 before processing are indicated by dashed lines. Blobs 70 correspond to white closed regions in binarized image data D1.

Here, it is assumed, for example, a case where blob 70 indicates a pair of electrode portions formed at both ends of component 92 in a longitudinal direction, and a case where blob 70 indicates the entirety including a body of component 92. The cases are different from each other depending on the type of component 92 (including color and gloss of the body and electrode portions) and a threshold used for binarization. In the present embodiment, in recognition processing (S20), component 92 is recognized by one or more blobs 70. Mounting assistance device 50 can determine in which way blob 70 is formed, based on component data M2.

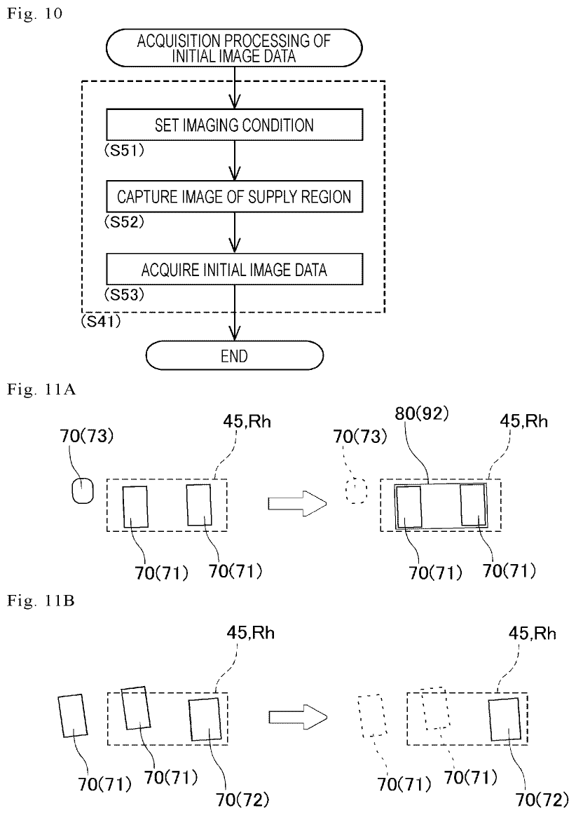

However, as illustrated in FIGS. 11A and 11B, blob 70 of binarized image data D1 may include elements such as foreign matter 89 and component 92 that is not accommodated in cavity 45. When defective blobs 72 and 73 are erroneously recognized as some of component 92, accuracy of the recognition processing is reduced. Therefore, state recognition section 51 extracts candidate blob 71 suitable for the recognition processing among multiple blobs 70 (S22). In other words, the extraction step is a process of removing blobs 70 (72 and 73) that are unsuitable for recognition processing,

Specifically, as illustrated in FIGS. 11A and 11B, state recognition section 51 extracts candidate blob 71 included in appropriate region Rh (S22). In detail, state recognition section 51 extracts candidate blob 71 when all the pixels constituting blob 70 are inside appropriate region Rh. “Appropriate region Rh” described above is a region defined based on a position, an angle, and a shape of cavity 45, and is a region that can be expected as blob 70 of component 92 accommodated in the normal posture.

In the present embodiment, “appropriate region Rh” is set mainly in consideration of an allowable error in a region having the same shape as cavity 45 indicated by cavity information M3. State recognition section 51 extracts blob 70 included in appropriate region Rh as candidate blob 71. Accordingly, as illustrated in FIGS. 11A and 11B, blob 70 located outside cavity 45 is removed (defective blobs 72 and 73 indicated by dashed lines on the right side).

Accordingly, for example, defective blob 72 corresponding to a closed region of component 92 not accommodated in cavity 45, and defective blob 73 corresponding to foreign matter 89 located outside cavity 45 can be removed so as not to be used in subsequent processing. In extraction step (S22), depending on a relationship with the subsequent processing, extraction using blob 70 and appropriate region Rh described above can be omitted, and an aspect in which candidate blob 71 corresponding to a closed region of at least a part of component 92 among multiple blobs 70 is extracted (partial inclusion of a defective blob is permitted) can be simply adopted.

Subsequently, state recognition section 51 performs recognition step (S23) of recognizing a rectangular region including one or more candidate blobs 71 as component 92 of image data D1. In the present embodiment, as illustrated in FIG. 11A, state recognition section 51 recognizes a rectangular region circumscribing one or more candidate blobs 71 as component 92 of image data D1. Accordingly, for example, recognition component 80 configured with pair of candidate blobs 71 and recognition component 80 configured with one candidate blob 71 are acquired.

State recognition section 51 also recognizes information required for subsequent processing such as reference position, an angle (supply angle), a shape (including lengths of a short side and a long side), and an area (corresponding to the number of pixels included in a rectangular region) of each of multiple recognition components 80 in supply region As. By such processing, state recognition section 51 recognizes a supply state of component 92 in supply region As and stores a recognition result in storage section 21.

In recognition processing (S20) described above, it is assumed that component mounter 10 sets only component 92 appropriately accommodated in cavity 45 as a target of a collection operation. Thus, when bulk feeder 30 is a type that does not have cavity 45 in supply region As, for example, state recognition section 51 may extract candidate blob 71 from among multiple blobs 70 under a condition that candidate blob 71 has an area of a certain range and a blob shape close to a rectangular shape, and may acquire a position and a shape of recognition component 80 in supply region As.

### 4-2. Determination Section 52

Determination section 52 determines whether component 92 (recognition component 80) recognized in recognition processing (S20) is suitable for a target of a collection operation by component mounter 10 based on a supply state of component 92 (S30). Here, in recognition processing (S20), even when recognition component 80 is recognized by using candidate blob 71 corresponding to a closed region of at least a part of component 92, there is a case where recognition component 80 is not suitable for the collection operation.

As a cause thereof, for example, it is assumed that two components 92 are accommodated in cavity 45 in an abnormal posture such that longitudinal directions thereof are oriented vertically. In such a case, it is assumed that an electrode portion of each component 92 is erroneously recognized as an electrode portion of one component 92 and recognition component 80 is recognized. In addition, when removal processing of blob 70 outside cavity 45 is omitted in recognition processing (S20), it is assumed that defective blob 73 corresponding to foreign matter 89 is erroneously recognized as a part of component 92 and recognition component 80 is recognized.

Determination section 52 first determines whether blob 70 is acceptable (S31). Various aspects can be adopted for determination of the acceptability of blob 70. For example, when a ratio of an area of one or more candidate blobs 71 included in a rectangular region with respect to an area of recognition component 80 exceeds a threshold set in advance, determination section 52 determines that candidate blob 71 occupies a predetermined area corresponding to an electrode portion and determines that candidate blob 71 is “good”. On the other hand, when an area of candidate blob 71 is small, it is determined that there is a possibility that a foreign matter in cavity 45 is recognized as an electrode portion and candidate blob 71 is determined to be “defective”.

In addition, in determination processing (S31), determination section 52 may determine whether candidate blob 71 is appropriate in a positional relationship with appropriate region Rh. As described above, when candidate blob 71 constituting recognition component 80 is determined to be “defective”, recognition component 80 is excluded from a target of subsequent determination processing.

Next, determination section 52 determines whether recognition component 80 is component 92 supplied to be collectable in supply region As (S32). Specifically, determination section 52 determines whether recognition component 80 is suitable for a collection operation based on whether at least one of a position, an angle, a shape, and an area of recognition component 80 is within a possible range when recognition component 80 is accommodated in a normal posture.

Determination processing (S30) including determination of the acceptability of blobs (S31) and suitableness determination of recognition component 80 (S32) described above is subsequently performed for all recognition components 80 recognized by state recognition section 51. Accordingly, mounting assistance device 50 acquires a determination result of whether each of multiple recognition components 80 is suitable for a collection operation. The determination result is stored as, for example, information indicating whether component 92 that can be collected is accommodated in each of multiple cavities 45. In addition, information, such as reference position (center position) and supply angle, is associated with collectable component 92.

### 4-3. Acquisition Section 53

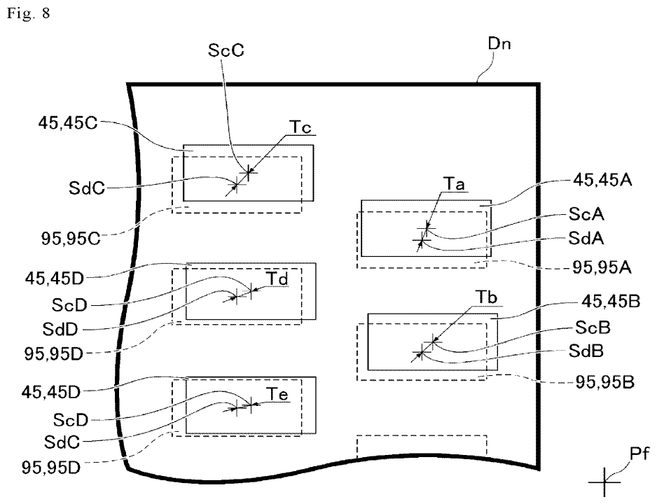

As described above, appropriate region Rh used in extraction processing (S22) of candidate blob 71 and the acceptability determination (S31) of the blob 70 is set based on cavity information M3. Cavity information M3 includes positions, angles, and shapes of multiple cavities 45. A position of cavity 45 is recorded as, for example, a relative position with respect to reference position Pf of supply region As. Here, as indicated by a dashed line in FIG. 8, design-based cavity 45 (ideal cavity 95) can be drawn with reference to reference position Pf in supply region As.

However, since actual cavity 45 is formed, for example, by processing a plate member fixed to track main body 41, a processing error can be included in a position, an angle, and a shape. Accordingly, center positions ScA to ScE of actual cavities 45 have errors Ta to Te with respect to center positions SdA to SdE of ideal cavities 95A to 95E (FIG. 8 exaggeratedly shows the errors), respectively. That is, for example, when appropriate region Rh is set by adding a tolerance to a position, an angle, and a shape of design-based cavity 45 (ideal cavity 95), it is assumed that actual cavity 45 is included in the region, but appropriate region Rh is greater than actual cavity 45.

Then, for example, in extraction processing (S22) of candidate blob 71, there is a possibility that blob 70 located inside appropriate region Rh regardless of being located outside actual cavity 45 cannot be removed as defective blob 72 and is extracted as candidate blob 71. Therefore, mounting assistance device 50 of the present embodiment adopts a configuration for acquiring cavity information M3 based on an actual state of multiple cavities 45 in supply region As of bulk feeder 30 that supplies component 92.

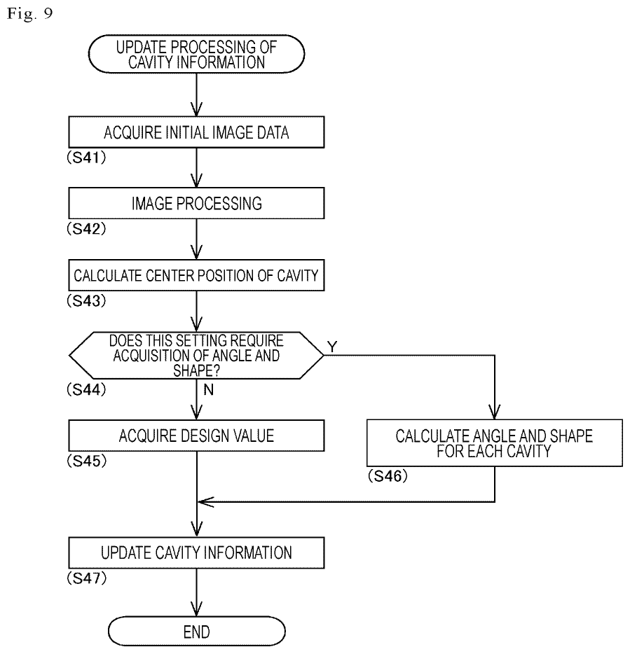

Acquisition section 53 performs image processing on initial image data Dn acquired by capturing supply region As in a state where components 92 are removed from supply region As, and acquires cavity information M3 on multiple cavities 45. In detail, as illustrated in FIG. 9, initial image data Dn is acquired first by capturing with a camera (S41). In the present embodiment, the camera is board camera 15 used for capturing an image of board 91 positioned inside component mounter 10. Details of the acquisition processing of initial image data Dn will be described below.

Next, acquisition section 53 performs image processing on initial image data Dn (see FIG. 8) (S42). The image processing includes, for example, binarization processing and edge detection. Accordingly, acquisition section detects outer shapes of multiple cavities 45 of initial image data Dn. Subsequently, acquisition section 53 calculates a center position of each cavity 45 (S43). In detail, acquisition section 53 may calculate the center position from an intersection of diagonal lines in the detected outer shape of cavity 45, or may calculate the center or the center of gravity of a closed region recognized as cavity 45 as the center position.

Acquisition section 53 calculates a coordinate value of the center position of each of multiple cavities 45 based on position coordinates of board camera 15 positioned when image-capturing is performed to acquire initial image data Dn. In this case, for example, when reference mark 49 is included in initial image data Dn, a position (center position) of each of multiple cavities 45 with respect to reference position Pf indicated by reference mark 49 may be calculated. Accordingly, when calibration processing using reference mark 49 is performed later and reference position Pf is obtained, a coordinate value of the center position of cavity 45 inside a component mounter is obtained.

Here, the information obtained from actual cavity 45 and design-based information may be mixed in cavity information M3. For example, among a position, an angle, a shape, a depth, and the type of a corresponding component as cavity information M3, acquisition section 53 may acquire the position, the angle, and the shape that can be obtained from initial image data Dn. In contrast to this, for example, regarding an angle and a shape of cavity 45, when there is a situation in which a processing error is small or an influence on image processing is small even if there is the processing error, acquisition section 53 may acquire only the obtained position of cavity 45.

For example, cavity information M3 is set in advance to identify the information obtained by initial image data Dn. When it is set that the angle and the shape of cavity 45 do not need to be acquired (S44: No), acquisition section 53 acquires a design value on the assumption that all the angles and the shapes are formed in an ideal angle and an ideal shape (S45). On the other hand, when it is set that an angle and a shape of cavity 45 need to be acquired (S44: Yes), acquisition section 53 further performs image processing to calculate the angle and the shape of each of multiple cavities 45 (S46).

Finally, acquisition section 53 updates cavity information M3 by adding the angle and shape acquired in S45 or S46 to positions (center positions) of multiple cavities 45 calculated in S43 (S47). Cavity information M3 is stored in storage section 21 of control device 20 and in host computer 60 as a management device.

### 4-4. Information Management Section 54

When a collection operation with setting component 92 supplied by predetermined bulk feeder 30 as a target is performed, mounting assistance device 50 performs image processing in the recognition processing of a supply state by using cavity information M3 acquired and updated by acquisition section 53. Information management section 54 manages cavity information M3.

In the present embodiment, when track unit 40 as a track member is detached from feeder main body 31, information management section 54 deletes cavity information M3 or restricts use of cavity information M3. That is, information management section 54 validates cavity information M3 even when bulk feeder 30 moves between two slots 121 or moves between component mounter 10 and setup device 65.

However, when track unit 40 is detached from feeder main body 31, information management section 54 determines that there is a possibility that a positional relationship of multiple cavities 45 with respect to reference position Pf indicated by reference mark 49 changes, and deletes cavity information M3 or restricts the use of cavity information M3. An administrator of mounting assistance device 50 can appropriately set criteria for the deletion and the restriction of use. For example, the criteria may be relaxed more than the above description, and the deletion of cavity information M3 and the restriction of use may be performed when a plate member forming cavity 45 is detached from track main body 41.

According to such a configuration, it is possible to prevent cavity information M3 in which an error occurs from being used due to a change in positional relationship between reference position Pf and multiple cavities 45 caused by detachment or the like of track unit 40. Accordingly, generation and update of cavity information M3 are prompted again, and it is possible to prevent a decrease in accuracy of image processing.

### 4-5. Condition Setting Section 55

Condition setting section 55 sets an imaging condition applied to the image-capturing for acquiring initial image data Dn to a condition under which an outer edge and a bottom surface of cavity 45 are partitioned, unlike an imaging condition applied to the image-capturing for acquiring image data D1 used in the recognition processing of a supply state. In acquisition processing (S41) of initial image data Dn by capturing with a camera, condition setting section 55 sets an imaging condition as illustrated in FIG. 10 (S51).

Here, in the image-capturing for acquiring image data D1 used in the image processing of recognition processing of a supply state, it is preferable that cavity 45 is not captured for the subsequent generation processing of blob 70 or an outer shape of cavity 45 is removed (converted into black) by binarization processing. Since initial image data Dn is used to recognize a shape of cavity 45, an outer shape of cavity 45 is preferably captured.

Therefore, condition setting section 55 adjusts a light source (incident light, side light, or the like), an exposure time, and the like as an imaging condition for acquiring initial image data Dn, and sets the conditions for partitioning an outer edge and a bottom surface of cavity 45. This setting may be performed by reading the setting set in advance by an administrator, or may be performed by searching for a condition for recognizing an outer edge while repeating image-capturing and image processing. In addition to setting one imaging condition, condition setting section 55 may set multiple types of imaging conditions on the assumption that image-capturing is performed multiple times.

Mounting assistance device 50 captures an image of supply region As under an imaging condition set by condition setting section 55 (S52) and acquires initial image data Dn (S53). Here, when multiple imaging conditions are set, mounting assistance device 50 may capture an image multiple times for each imaging condition (S52), and thereby, initial image data Dn that can recognize an outer edge of cavity 45 may be acquired by combining multiple pieces of acquired image data (S53). According to such a configuration, suitable initial image data Dn is acquired, and outer edges of multiple cavities 45 are recognized with high accuracy in subsequent image processing (S42),

### 5. Mounting Process by Component Mounter 10

A mounting process performed by component mounter 10 will be described. Here, it is assumed that bulk feeder 30 is mounted on component supply device 12. After bulk feeder 30 is set in slot 121, control device 20 performs calibration processing and recognizes positions of multiple cavities 45 inside a component mounter. In the above-described calibration processing, control device 20 first moves board camera 15 to a position above reference mark 49 of bulk feeder 30 and acquires image data by capturing with board camera 15.

Then, control device 20 recognizes reference position Pf as a position of bulk feeder 30 inside a component mounter based on positions of pair of reference marks 49 included in the image data by image processing and a position of board camera 15 when image-capturing. Control device 20 can acquire a coordinate value of each cavity 45 based on a result of calibration processing and cavity information M3 indicating an arrangement of cavities 45.

In a mounting process, board conveyance device 11 of component mounter 10 first performs a loading process of board 91. Accordingly, board 91 is loaded into a component mounter and positioned at a predetermined position inside the component mounter. Control device 20 causes bulk feeder 30 to perform a supply operation after or in parallel with the loading process of board 91. By performing the supply operation, multiple components 92 are accommodated in at least some of multiple cavities 45 of bulk feeder 30. After the supply operation by bulk feeder 30 is completed, mounting assistance device 50 performs recognition processing of a supply state of component 92.

Accordingly, identification information (such as an address of cavity 45) of cavity 45 that accommodates current component 92 in a collectable manner as a supply state, and a reference position and a supply angle of collectable component 92 (component 92 suitable for a collection operation) are acquired. Next, control device 20 performs a PP cycle. In the PP cycle, control device 20 performs a collection cycle in which a collection operation for collecting components 92 is repeated by using multiple suction nozzles 134. In this case, control device 20 controls an operation of mounting head 133 in a collection position of collectable component 92. In this case, control device 20 determines an angle of suction nozzle 134 according to a supply angle of collectable component 92.

Subsequently, control device 20 performs recognition processing of a holding state of components 92 respectively held by multiple suction nozzles 134. In detail, control device 20 moves mounting head 133 to a position above part camera 14 and sends an imaging command to part camera 14. Control device 20 performs image processing on the image data acquired by capturing with part camera 14 and recognizes a posture (position and angle) of component 92 held by each of multiple suction nozzles 134. A result of the recognition processing of a holding state is recorded in storage section 21 as an operation result indicating whether collection mistake occurs in the collection operation.

Thereafter, control device 20 performs a mounting cycle in which a mounting operation for mounting components is repeated by using multiple suction nozzles 134. In the mounting operation of the mounting cycle, control device 20 controls an operation of mounting head 133 such that each of components 92 is mounted at a mounting position designated by control program M1. Further, control device 20 controls an operation of mounting head 133 such that suction nozzle 134 is positioned and an angle thereof is determined with respect to a mounting position based on a result of the recognition processing.

In addition, control device 20 performs supply management processing of component 92 in parallel with the PP cycle described above. The supply management processing includes setting of performance timing of a supply operation of component 92 by bulk feeder 30, a command of the supply operation, recognition processing of a supply state, and the like. For example, when a supply operation of component 92 is performed, the supply operation by bulk feeder 30 is performed in a period from the completion of a collection cycle of a current PP cycle to the start of a collection cycle of the next PP cycle. When the supply operation by bulk feeder 30 is performed, mounting assistance device 50 performs again the recognition processing of the supply state described above.

Control device 20 performs an unloading process of board 91 when all the PP cycles are completed based on control program M1. In the unloading process of board 91, board conveyance device 11 unclamps positioned board 91 and unloads board 91 out of component mounter 10.

### 6. Effect of Configuration of Embodiment

According to a configuration of mounting assistance device 50 described above, it is possible to improve accuracy of image processing in recognition processing of a supply state of component 92 supplied by bulk feeder 30. Accordingly, it is possible to prevent a mistake from occurring in a collection operation by component mounter 10, and as a result, it is possible to maintain high productivity in component mounter 10.

### 7. Modification of Embodiment

In the embodiment, a configuration is adopted in which mounting assistance device 50 is incorporated in control device 20 of component mounter 10. In contrast to this, a part or all of mounting assistance device 50 may be incorporated into host computer 60 and an external device used for setup or maintenance of bulk feeder 30.

For example, acquisition section 53 of mounting assistance device 50 may be incorporated into setup device 65 as an external device. Setup device 65 includes support table 66 that supports bulk feeder 30, and dedicated camera 67 that can capture supply region As of bulk feeder 30 supported by support table 66. For example, after track unit 40 is attached to feeder main body 31, acquisition section 53 acquires initial image data Dn by capturing supply region As by dedicated camera 67.

Acquisition section 53 performs the same processing as in the embodiment, associates cavity information M3 with identification information (ID) for identifying bulk feeder 30, and stores cavity information M3 in host computer 60 that manages setup device 65 and component mounter 10. When bulk feeder 30 is mounted on slot 121 of predetermined component mounter 10, control device 20 acquires identification information (ID) of bulk feeder 30 by communication, sends the identification information (ID) to host computer 60, and inquires whether the use for a mounting process to be performed is permitted.

When bulk feeder 30 is suitable for a predetermined mounting process, host computer 60 permits bulk feeder 30 to be used and sends cavity information M3 corresponding to bulk feeder 30 to control device 20. As described above, component mounter 10 acquires cavity information M3 associated with identification information (ID) from host computer 60 based on the identification information (ID) of bulk feeder 30 mounted on component supply device 12. When the mounting process is performed, the recognition processing of a supply state of a component using cavity information M3 is performed. This configuration has also the same effect as in the embodiment.

In the embodiment, a color arrangement between a portion constituting an outer edge of cavity 45 and a bottom surface of cavity 45 is not limited. However, an outer edge portion and the bottom surface of cavity 45 may have different colors from each other. For example, a base plate constituting the bottom surface of cavity 45 is black, and an upper surface of a mask plate in which a through hole constituting a side surface of cavity 45 is formed is gray with higher brightness than the bottom surface.

It can be expected that initial image data Dn acquired by capturing supply region As configured as described above is subjected to the image processing (S42) and an outer edge of cavity 45 is more suitably acquired. However, brightness of a gray color of an upper surface of a mask plate is set to be lower than the brightness of an electrode portion corresponding to blob 70 in component 92. Accordingly, an upper surface of a mask plate and a bottom surface of cavity 45 have the same black color due to binarization in image processing of recognition processing of a supply state of a component, and do not influence the subsequent image processing. This configuration has also the same effect as in the main embodiment.

### REFERENCE SIGNS LIST

10: component mounter, 12: component supply device, 13: component transfer device, 131: head drive device, 132: mounting body, 133: mounting head, 134: suction nozzle, 14: part camera, 15: board camera, 20: control device, 21: storage section, 30: bulk feeder, 31: feeder main body, 40: track unit (track member), 45; cavity, 48: shutter, 49: reference mark, 50: mounting assistance device, 51: state recognition section, 52: determination section, 53: acquisition section, 54: information management section, 55: condition setting section, 60: host computer (host device), 65: setup device (external device), 66: support table, 67: dedicated camera, 70: blob, 71: candidate blob, 72, 73: defective blob, 80: recognition component, 89: foreign matter, 91: board, 92: component, 95, 95A to 95E: ideal cavity, As: supply region, R; conveyance path, M1: control program, M2: component data, M3: cavity information, D1: image data, Dn: initial image data, Rh: appropriate region, Pf: reference position

1. A mounting assistance device to be applied to a component mounter configured to collect a component from a component supply device equipped with a bulk feeder having multiple cavities each of which accommodates a component in a supply region where the component is supplied to be collectable, the component mounter being configured to mount the component on a board, the mounting assistance device comprising:
an acquisition section configured to perform image processing on initial image data acquired by capturing the supply region in a state where the components are removed from the supply region, and acquire cavity information on the multiple cavities.

2. The mounting assistance device according to claim 1, wherein
the component mounter includes a camera capable of capturing the supply region of the bulk feeder mounted on the component supply device,
the initial image data is acquired by capturing with the camera, and
the acquisition section acquires a position of each of the multiple cavities with respect to a reference position of the supply region as the cavity information by the image processing.

3. The mounting assistance device according to claim 2, wherein the camera is a board camera used for capturing the board positioned inside the component mounter.

4. The mounting assistance device according to claim 1, wherein
an external device used for setup or maintenance of the bulk feeder includes a support table configured to support the bulk feeder and a camera capable of capturing the supply region of the bulk feeder supported by the support table,
the initial image data is acquired by capturing with the camera,
the bulk feeder includes a reference mark indicating a reference position of the supply region, and
the acquisition section acquires a position of each of the multiple cavities with respect to the reference mark as the cavity information by the image processing.

5. The mounting assistance device according to claim 4, wherein the acquisition section stores the cavity information in association with identification information for identifying the bulk feeder in a management device configured to manage the external device and the component mounter.

6. The mounting assistance device according to claim 5, wherein the component mounter acquires the cavity information associated with the identification information from the management device, based on the identification information of the bulk feeder mounted on the component supply device.

7. The mounting assistance device according to claim 1, wherein
the bulk feeder includes a feeder main body and a track member that is detachably provided to the feeder main body, the supply region being formed in the track member, and
the mounting assistance device further comprises an information management section configured to delete the cavity information or restrict use of the cavity information when the track member is detached from the feeder main body.

8. The mounting assistance device according to claim 1, further comprising:
a state recognition section configured to, after the bulk feeder mounted on the component supply device performs a supply operation of supplying the component, perform image processing on image data acquired by capturing the supply region by using the cavity information, and recognize a supply state of the component in the supply region.

9. The mounting assistance device according to claim 8, wherein the image processing includes a generation step of generating multiple blobs by binarizing the image data, an extraction step of extracting a candidate blob corresponding to a closed region of at least a part of the component among the multiple blobs based on the cavity information, and a recognition step of recognizing a rectangular region including one or more candidate blobs as the component in the image data.

10. The mounting assistance device according to claim 8, further comprising:
a condition setting section configured to set an imaging condition applied to image-capturing for acquiring the initial image data as a condition that is different from an imaging condition applied to image-capturing for acquiring the image data used for recognition processing of the supply state, an outer edge and a bottom surface of the cavity being defined in the condition.

11. The mounting assistance device according to claim 1, wherein the acquisition section acquires at least one of positions, angles, and shapes of the multiple cavities in the supply region as the cavity information.

12. The mounting assistance device according to Claim 1, wherein the acquisition section acquires positions of the multiple cavities in the supply region as the cavity information.
